(19) United States
(12) Patent Application Publication
(10) Pub. No.: US 2008/0166564 A1
(43) Pub. Date: Jul. 10, 2008

(54) DERIVATIZED MONOMERS FOR MAKING CONDUCTIVE POLYMERS, AND DEVICES MADE WITH SUCH POLYMERS

(76) Inventors: Vsevolod Rostovtsev, Swarthmore, PA (US); Che-Hsiung Hsu, Wilmington, DE (US); Charles J. DuBois, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/960,318

(22) Filed: Dec. 19, 2007

Related U.S. Application Data
(60) Provisional application No. 60/877,508, filed on Dec. 28, 2006.

(51) Int. Cl. B32B 27/00; C08G 79/00; C07C 31/38; C07D 333/02

(52) U.S. Cl. 428/411.1; 528/401; 568/842; 549/29

(57) ABSTRACT

There is provided a derivatized conductive monomer and polymer made therefrom. The derivatized monomer has a fluorinated acid substituent. There are also provided electronic devices having a buffer layer containing the polymer.

### RELATED APPLICATION

This application claims priority under 35 U.S.C. § 119(e) from U.S. Provisional Application 60/877,508 filed on Dec. 28, 2006, which is incorporated by reference in its entirety herein.

### BACKGROUND INFORMATION

1. Field of the Disclosure

This disclosure relates in general to derivatized monomers for making conductive polymers, and the use of the polymers in organic electronic devices.

2. Description of the Related Art

Organic electronic devices define a category of products that include an active layer. Such devices convert electrical energy into radiation, detect signals through electronic processes, convert radiation into electrical energy, or include one or more organic semiconductor layers.

Organic light-emitting diodes (OLEDs) are organic electronic devices comprising an organic layer capable of electroluminescence. OLEDs can have the following configuration, with additional optional layers possible:
anode/buffer layer/EL material/cathode
   The anode is typically any material that is transparent and has the ability to inject holes into the EL material, such as, for example, indium/tin oxide (ITO). The anode is optionally supported on a glass or plastic substrate. EL materials include fluorescent compounds, fluorescent and phosphorescent metal complexes, conjugated polymers, and mixtures thereof. The cathode is typically any material (such as, e.g., Ca or Ba) that has the ability to inject electrons into the EL material. The buffer layer is typically an electrically conducting polymer and facilitates the injection of holes from the anode into the EL material layer. The buffer layer may also have other properties which facilitate device performance.

There is a continuing need for buffer materials.

### SUMMARY

There is provided a derivatized monomer having the formula PCM-(FAS)ₓ wherein:

PCM is a precursor conductive monomer,

FAS is a fluorinated acid substituent, and
x is an integer from 1-5.

There is also provided a polymer made from the derivatized monomer.

There is also provided an electronic device having at least one active layer comprising a polymer made from the derivatized monomer.

There is also provided an electronic device comprising an anode, a cathode, and an active layer therebetween. The device further has a layer adjacent the anode comprising a polymer made from the derivatized monomer.

The foregoing general description and the following detailed description are exemplary and explanatory only and are not restrictive of the invention, as defined in the appended claims.

### BRIEF DESCRIPTION OF THE FIGURE

Embodiments are illustrated in the accompanying figure to improve understanding of concepts as presented herein.

FIG. 1 includes a schematic diagram of an electronic device.

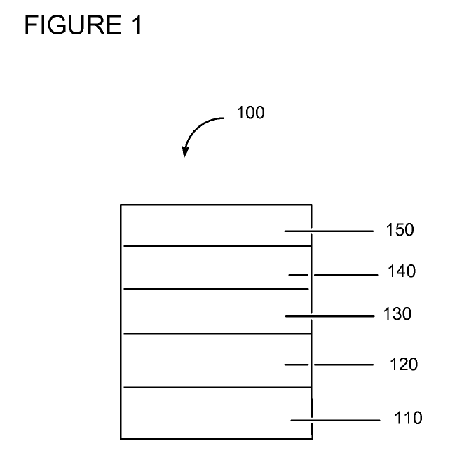

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Derivatized Conductive Monomers, Conductive Polymers, Electronic Devices, and finally, Examples.

### 1. Definitions and Clarification of Terms

Before addressing details of embodiments described below, some terms are defined or clarified.

As used herein, the term “conductive monomer” is intended to refer to a monomer, which when polymerized forms an electrically conductive polymer. The term “electrically conductive polymer” refers to a polymeric material which is inherently or intrinsically capable of electrical conductivity without the addition of carbon black or conductive metal particles.

The term “derivatized” as it refers to a compound, i.e., a monomer, is intended to mean that the compound has at least one substituent.

The term “fluorinated acid substituent” refers to a substituent having acidic groups, where at least some of the hydrogens have been replaced by fluorine. The term “acidic group” refers to a group capable of ionizing to donate a hydrogen ion to a Brønsted base.

The term “polymer” is intended to refer to compounds having at least three repeating units and encompasses homopolymers and copolymers.

The term “conductor” and its variants are intended to refer to a layer material, member, or structure having an electrical property such that current flows through such layer material, member, or structure without a substantial drop in potential. The term is intended to include semiconductors. In one embodiment, a conductor will form a layer having a conductivity of at least 10⁻⁶ S/cm.

The term “work function” is intended to mean the minimum energy needed to remove an electron from a conductive or semiconductive material to a point at infinite distance away from the surface. The work-function is commonly obtained by UPS (Ultraviolet Photoemission Spectroscopy) or Kelvin-probe contact potential differential measurement.

The term “energy potential” is intended to mean potential of a non-conducting material sandwiched between a conducting specimen and a vibrating tip of Kelvin probe. The conducting specimen can be, but not limited to either gold, indium tin oxide, or electrically conducting polymers. The non-conducting materials in this invention is hole-transporting materials.

The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device.

“Hole transport” when referring to a layer, material, member, or structure, is intended to mean such layer, material, member, or structure facilitates migration of positive charges through the thickness of such layer, material, member, or structure with relative efficiency and small loss of charge. As used herein, the term “hole transport layer” does not encompass a light-emitting layer, even though that layer may have some hole transport properties.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} St Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, lighting source, photodetector, photovoltaic, and semiconductive member arts.

### 2. Derivatized Conductive Monomer

The derivatized conductive monomer has the formula PCM-(FAS)ₓ wherein:

PCM is a precursor conductive monomer,

FAS is a fluorinated acid substituent, and

x is an integer from 1-5.

In some embodiments, x=1.
a. Precursor Conductive Monomers

In one embodiment, the precursor monomer is selected from the group consisting of thiophenes, pyrroles, anilines, and polycyclic aromatics. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In one embodiment, the polycyclic aromatic precursor monomer is a thienothiophene.

In one embodiment, thiophene monomers contemplated for use to form the derivatized conductive monomer comprise Formula I below:

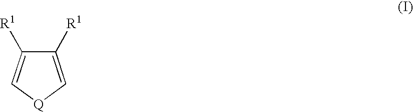

wherein:
Q is selected from the group consisting of S, Se, and Te;
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, selenium, tellurium, sulfur or oxygen atoms.

As used herein, the term “alkyl” refers to a group derived from an aliphatic hydrocarbon and includes linear, branched and cyclic groups which may be unsubstituted or substituted. The term “heteroalkyl” is intended to mean an alkyl group, wherein one or more of the carbon atoms within the alkyl group has been replaced by another atom, such as nitrogen, oxygen, sulfur, and the like. The term “alkylene” refers to an alkyl group having two points of attachment.

As used herein, the term “alkenyl” refers to a group derived from an aliphatic hydrocarbon having at least one carbon-carbon double bond, and includes linear, branched and cyclic groups which may be unsubstituted or substituted. The term “heteroalkenyl” is intended to mean an alkenyl group, wherein one or more of the carbon atoms within the alkenyl group has been replaced by another atom, such as nitrogen, oxygen, sulfur, and the like. The term “alkenylene” refers to an alkenyl group having two points of attachment.

As used herein, the following terms for substituent groups refer to the formulae given below:
“alcohol” —R³—OH
“amido” —R³—C(O)N(R⁶)R⁶
“amidosulfonate” —R³—C(O)N(R⁶)R⁴— SO₃Z
“benzyl” —CH₂—C₆H₅
“carboxylate” —R³—C(O)O-Z or —R³—O—C(O)-Z
“ether” —R³—(O—R⁵)ₚ—O—R⁵
“ether carboxylate” —R³—O—R⁴—C(O)O-Z or —R³—O—R⁴—O—C(O)-Z
“ether sulfonate” —R³—O—R⁴—SO₃Z
“ester sulfonate” —R³—O—C(O)—R⁴—SO₃Z
“sulfonimide” —R³—SO₂—NH—SO₂—R⁵
“urethane” —R³—O—C(O)—N(R⁶)₂
where all “R” groups are the same or different at each occurrence and:
   R³ is a single bond or an alkylene group
   R⁴ is an alkylene group
   R⁵ is an alkyl group
   R⁶ is hydrogen or an alkyl group
   p is 0 or an integer from 1 to 20
   Z is H, alkali metal, alkaline earth metal, N(R⁵)₄ or R⁵
      Any of the above groups may further be unsubstituted or substituted, and any group may have F substituted for one or more hydrogens, including perfluorinated groups. In one embodiment, the alkyl and alkylene groups have from 1-20 carbon atoms.

In one embodiment, in the thiophene monomer, both R¹ together form —O—(CHY)ₘ—O—, where m is 2 or 3, and Y is the same or different at each occurrence and is selected from hydrogen, halogen, alkyl, alcohol, amidosulfonate, benzyl, carboxylate, ether, ether carboxylate, ether sulfonate, ester sulfonate, and urethane, where the Y groups may be partially or fully fluorinated. In one embodiment, all Y are hydrogen. In one embodiment, the polythiophene is poly(3,4-ethylenedioxythiophene). In one embodiment, at least one Y group is not hydrogen. In one embodiment, at least one Y group is a substituent having F substituted for at least one hydrogen. In one embodiment, at least one Y group is perfluorinated.

In one embodiment, the thiophene monomer has Formula I(a):

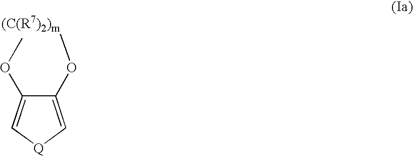

wherein:
Q is selected from the group consisting of S, Se, and Te;
R⁷ is the same or different at each occurrence and is selected from hydrogen, alkyl, heteroalkyl, alkenyl, heteroalkenyl, alcohol, amidosulfonate, benzyl, carboxylate, ether, ether carboxylate, ether sulfonate, ester sulfonate, and urethane, with the proviso that at least one R⁷ is not hydrogen, and
m is 2 or 3.

In one embodiment of Formula I(a), m is two, one R⁷ is an alkyl group of more than 5 carbon atoms, and all other R⁷ are hydrogen. In one embodiment of Formula I(a), at least one R⁷ group is fluorinated. In one embodiment, at least one R⁷ group has at least one fluorine substituent. In one embodiment, the R⁷ group is fully fluorinated.

In one embodiment, pyrrole monomers contemplated for use to form the derivatized conductive monomer comprise Formula II below.

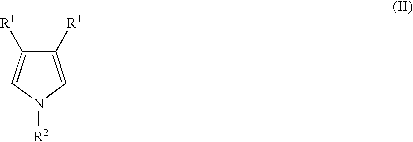

where in Formula II:
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, amidosulfonate, ether carboxylate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms; and
R² is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, alcohol, benzyl, carboxylate, ether, ether carboxylate, ether sulfonate, ester sulfonate, and urethane.

In one embodiment, R¹ is the same or different at each occurrence and is independently selected from hydrogen, alkyl, alkenyl, alkoxy, cycloalkyl, cycloalkenyl, alcohol, benzyl, carboxylate, ether, amidosulfonate, ether carboxylate, ether sulfonate, ester sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties.

In one embodiment, R² is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one embodiment, the pyrrole monomer is unsubstituted and both R¹ and R² are hydrogen.

In one embodiment, both R¹ together form a 6- or 7-membered alicyclic ring, which is further substituted with a group selected from alkyl, heteroalkyl, alcohol, benzyl, carboxylate, ether, ether carboxylate, ether sulfonate, ester sulfonate, and urethane. These groups can improve the solubility of the monomer and the resulting polymer. In one embodiment, both R¹ together form a 6- or 7-membered alicyclic ring, which is further substituted with an alkyl group. In one embodiment, both R¹ together form a 6- or 7-membered alicyclic ring, which is further substituted with an alkyl group having at least 1 carbon atom.

In one embodiment, both R¹ together form —O—(CHY)ₘ—O—, where m is 2 or 3, and Y is the same or different at each occurrence and is selected from hydrogen, alkyl, alcohol, benzyl, carboxylate, amidosulfonate, ether, ether carboxylate, ether sulfonate, ester sulfonate, and urethane. In one embodiment, at least one Y group is not hydrogen. In one embodiment, at least one Y group is a substituent having F substituted for at least one hydrogen. In one embodiment, at least one Y group is perfluorinated.

In one embodiment, aniline monomers contemplated for use to form the derivatized conductive monomer comprise Formula III below.

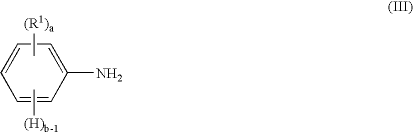

wherein:

a is 0 or an integer from 1 to 4;

b is an integer from 1 to 5, with the proviso that a+b=5; and R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur or oxygen atoms.

When polymerized, the aniline monomeric unit can have Formula IV(a) or Formula IV(b) shown below, or a combination of both formulae.

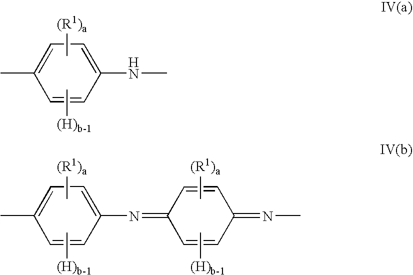

where a, b and R¹ are as defined above.

In one embodiment, the aniline monomer is unsubstituted and a=0.

In one embodiment, a is not 0 and at least one R¹ is fluorinated. In one embodiment, at least one R¹ is perfluorinated.

In one embodiment, fused polycylic heteroaromatic monomers contemplated for use to form the electrically conductive polymer in the new composition have two or more fused aromatic rings, at least one of which is heteroaromatic. In one embodiment, the fused polycyclic heteroaromatic monomer has Formula V:

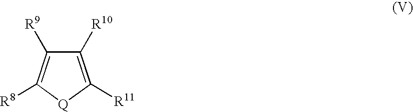

wherein:
Q is S, Se, Te, or NR⁶;
R⁶ is hydrogen or alkyl;
R⁸, R⁹, R¹⁰, and R¹¹ are independently selected so as to be the same or different at each occurrence and are selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; and
at least one of R⁸ and R⁹, R⁹ and R¹⁰, and R¹⁰ and R¹¹ together form an alkenylene chain completing a 5 or 6-membered aromatic ring, which ring may optionally include one or more divalent nitrogen, sulfur, selenium, tellurium, or oxygen atoms.

In one embodiment, the fused polycyclic heteroaromatic monomer has Formula V(a), V(b), V(c), V(d), V(e), V(f), and V(g):

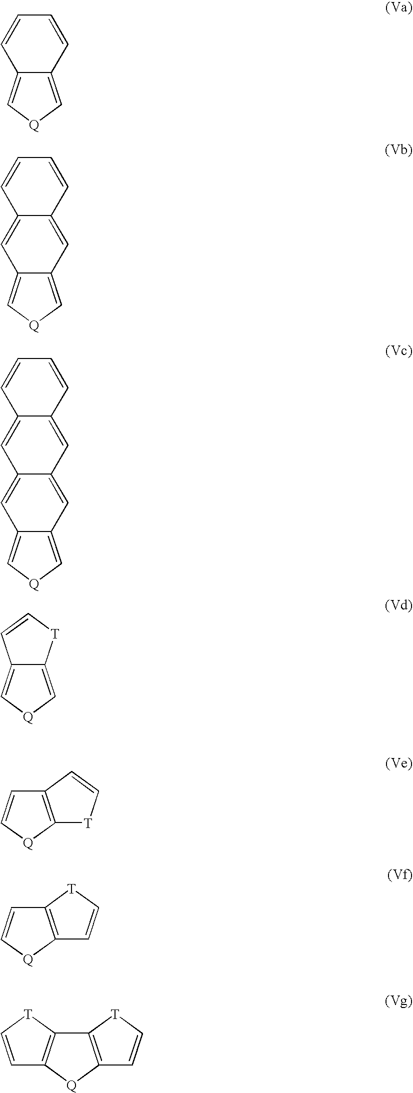

wherein:
Q is S, Se, Te, or NH; and
T is the same or different at each occurrence and is selected from S, NR⁶, O, SiR⁶₂, Se, Te, and PR⁶;
R⁶ is hydrogen or alkyl.
   The fused polycyclic heteroaromatic monomers may be further substituted with groups selected from alkyl, heteroalkyl, alcohol, benzyl, carboxylate, ether, ether carboxylate, ether sulfonate, ester sulfonate, and urethane. In one embodiment, the substituent groups are fluorinated. In one embodiment, the substituent groups are fully fluorinated.

In one embodiment, the fused polycyclic heteroaromatic monomer is a thieno(thiophene). Such compounds have been discussed in, for example, Macromolecules, 34, 5746-5747 (2001); and Macromolecules, 35, 7281-7286 (2002). In one embodiment, the thieno(thiophene) is selected from thieno(2,3-b)thiophene, thieno(3,2-b)thiophene, and thieno(3,4-b)thiophene. In one embodiment, the thieno(thiophene) monomer is further substituted with at least one group selected from alkyl, heteroalkyl, alcohol, benzyl, carboxylate, ether, ether carboxylate, ether sulfonate, ester sulfonate, and urethane. In one embodiment, the substituent groups are fluorinated. In one embodiment, the substituent groups are fully fluorinated.

In one embodiment, polycyclic heteroaromatic monomers contemplated for use to form the derivatized conductive monomer comprise Formula VI:

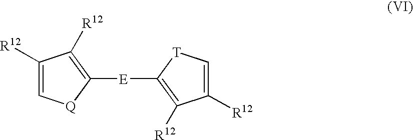

wherein:
Q is S, Se, Te, or NR⁶;
T is selected from S, NR⁶, O, SiR⁶₂, Se, Te, and PR⁶;
E is selected from alkenylene, arylene, and heteroarylene;
R⁶ is hydrogen or alkyl;
   R¹² is the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; or both R¹² groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms.
      b. Fluorinated Acid Substituents

The fluorinated acid substituent can be any substituent which is fluorinated and has acidic groups with acidic protons. The term includes partially and fully fluorinated substituents. In one embodiment, the fluorinated acid substituent is highly fluorinated. The term “highly fluorinated” means that at least 50% of the available hydrogens bonded to a carbon, have been replaced with fluorine. The acidic groups supply an ionizable proton. In one embodiment, the acidic proton has a pKa of less than 3. In one embodiment, the acidic proton has a pKa of less than 0. In one embodiment, the acidic proton has a pKa of less than −5. Examples of acidic groups include, but are not limited to, carboxylic acid groups, sulfonic acid groups, sulfonimide groups, phosphoric acid groups, phosphonic acid groups, and combinations thereof. In one embodiment, the fluorinated acid polymer is water-soluble. In one embodiment, the fluorinated acid polymer is dispersible in water.

In one embodiment, the acidic groups are sulfonic acid groups or sulfonimide groups. A sulfonimide group has the formula:

—SO₂—NH—SO₂—R

where R is an alkyl group.

In one embodiment, the acidic groups are on a fluorinated substituent group selected from the group consisting of alkyl groups, alkoxy groups, amido groups, ether groups, and combinations thereof.

In one embodiment, the fluorinated acid substituent has the formula:

—O(CF₂)_{b}SO₂OH

where b is an integer from 1 to 5.

In one embodiment, the fluorinated acid substituent has the formula:

—O(CF₂)_{b}SO₂NSO₂O(CF₂)_{b}H

where be is the same or different and is an integer from 1 to 5.

In one embodiment, the fluorinated acid substituent is a siloxane group having the formula below:

—OₐSi(OH)_{b-a}R²²_{3-b}R²³R_{f}SO₃H

wherein:

a is from 1 to b;

b is from 1 to 3;

R²² is a non-hydrolyzable group independently selected from the group consisting of alkyl, aryl, and arylalkyl;

R²³ is a bidentate alkylene radical, which may be substituted by one or more ether oxygen atoms, with the proviso that R²³ has at least two carbon atoms linearly disposed between Si and R_{f}; and

R_{f} is a perfluoralkylene radical, which may be substituted by one or more ether oxygen atoms.

In one embodiment, the fluorinated acid substituent has the Formula (XIV)

—O_{g}—[CF(R_{f}²)CF—Oₕ]ᵢ—CF₂CF₂SO₃H (XIV)
wherein R_{f}² is F or a perfluoroalkyl radical having 1-10 carbon atoms either unsubstituted or substituted by one or more ether oxygen atoms, h=0 or 1, i=0 to 3, and g=0 or 1.

In one embodiment, the fluorinated acid substituent is represented by the formula

—(O—CF₂CFR_{f}³)ₐ—O—CF₂CFR_{f}⁴SO₃E⁵

wherein R_{f}³ and R_{f}⁴ are independently selected from F, Cl or a perfluorinated alkyl group having 1 to 10 carbon atoms, a=0, 1 or 2, and E⁵ is H, and R1, R2, R3, and R4 are the same or different and are H, CH₃ or C₂H₅.

In one embodiment, the fluorinated acid substituent is represented by the formula

—O—CF₂CF(CF₃)—O—CF₂CF₂SO₃E⁵

where E5 is as defined above.

c. Preparation of Derivatized Conductive Monomers

The derivatized conductive monomers can be prepared starting with the precursor conductive monomers and using standard synthetic techniques, as discussed further in the examples.

### 3. Conductive Polymer

In one embodiment, an electrically conductive polymer composition is formed by the oxidative polymerization of the derivatized conductive monomer. In one embodiment, two or more different derivatized conductive monomers are used to form a copolymer.

In one embodiment, the oxidative polymerization is carried out in a homogeneous aqueous solution. In another embodiment, the oxidative polymerization is carried out in an emulsion of water and an organic solvent. In general, some water is present in order to obtain adequate solubility of the oxidizing agent and/or catalyst. Oxidizing agents such as ammonium persulfate, sodium persulfate, potassium persulfate, and the like, can be used. A catalyst, such as ferric chloride, or ferric sulfate may also be present. The resulting polymerized product will be a solution, dispersion, or emulsion of the conductive polymer derivatized with the fluorinated acid substituent.

In one embodiment, the electrically conductive polymer is a copolymer of a precursor monomer and at least one second monomer. Any type of second monomer can be used, so long as it does not detrimentally affect the desired properties of the copolymer. In one embodiment, the second monomer comprises no more than 50% of the polymer, based on the total number of monomer units. In one embodiment, the second monomer comprises no more than 30%, based on the total number of monomer units. In one embodiment, the second monomer comprises no more than 10%, based on the total number of monomer units.

Exemplary types of second monomers include, but are not limited to, alkenyl, alkynyl, arylene, and heteroarylene. Examples of second monomers include, but are not limited to, fluorene, oxadiazole, thiadiazole, benzothiadiazole, phenylenevinylene, phenyleneethynylene, pyridine, diazines, and triazines, all of which may be further substituted.

In one embodiment, the copolymers are made by first forming an intermediate precursor monomer having the structure A-B-C, where A and C represent precursor monomers, which can be the same or different, and B represents a second monomer. The A-B-C intermediate precursor monomer can be prepared using standard synthetic organic techniques, such as Yamamoto, Stille, Grignard metathesis, Suzuki, and Negishi couplings. The copolymer is then formed by oxidative polymerization of the intermediate precursor monomer alone, or with one or more additional precursor monomers.

In one embodiment, the electrically conductive polymer is a copolymer of two or more derivatized conductive monomers. In one embodiment, the derivatized conductive monomers are selected from a thiophene, a pyrrole, an aniline, and a polycyclic aromatic.

### (i) pH Adjustment

As synthesized, the aqueous dispersions of the new conductive polymer composition generally have a very low pH. In one embodiment, the pH is adjusted to higher values, without adversely affecting the properties in devices. In one embodiment, the pH of the dispersion is adjusted to from about 1.5 to about 4. In one embodiment, the pH is adjusted to between 3 and 4. It has been found that the pH can be adjusted using known techniques, for example, ion exchange or by titration with an aqueous basic solution.

In one embodiment, after completion of the polymerization reaction, the as-synthesized aqueous dispersion is contacted with at least one ion exchange resin under conditions suitable to remove decomposed species, side reaction products, and unreacted monomers, and to adjust pH, thus producing a stable, aqueous dispersion with a desired pH. In one embodiment, the as-synthesized aqueous dispersion is contacted with a first ion exchange resin and a second ion exchange resin, in any order. The as-synthesized aqueous dispersion can be treated with both the first and second ion exchange resins simultaneously, or it can be treated sequentially with one and then the other.

Ion exchange is a reversible chemical reaction wherein an ion in a fluid medium (such as an aqueous dispersion) is exchanged for a similarly charged ion attached to an immobile solid particle that is insoluble in the fluid medium. The term “ion exchange resin” is used herein to refer to all such substances. The resin is rendered insoluble due to the crosslinked nature of the polymeric support to which the ion exchanging groups are attached. Ion exchange resins are classified as cation exchangers or anion exchangers. Cation exchangers have positively charged mobile ions available for exchange, typically protons or metal ions such as sodium ions. Anion exchangers have exchangeable ions which are negatively charged, typically hydroxide ions.

In one embodiment, the first ion exchange resin is a cation, acid exchange resin which can be in protonic or metal ion, typically sodium ion, form. The second ion exchange resin is a basic, anion exchange resin. Both acidic, cation including proton exchange resins and basic, anion exchange resins are contemplated for use in the practice of the invention. In one embodiment, the acidic, cation exchange resin is an inorganic acid, cation exchange resin, such as a sulfonic acid cation exchange resin. Sulfonic acid cation exchange resins contemplated for use in the practice of the invention include, for example, sulfonated styrene-divinylbenzene copolymers, sulfonated crosslinked styrene polymers, phenol-formaldehyde-sulfonic acid resins, benzene-formaldehyde-sulfonic acid resins, and mixtures thereof. In another embodiment, the acidic, cation exchange resin is an organic acid, cation exchange resin, such as carboxylic acid, acrylic or phosphorous cation exchange resin. In addition, mixtures of different cation exchange resins can be used.

In another embodiment, the basic, anionic exchange resin is a tertiary amine anion exchange resin. Tertiary amine anion exchange resins contemplated for use in the practice of the invention include, for example, tertiary-aminated styrene-divinylbenzene copolymers, tertiary-aminated crosslinked styrene polymers, tertiary-aminated phenol-formaldehyde resins, tertiary-aminated benzene-formaldehyde resins, and mixtures thereof. In a further embodiment, the basic, anionic exchange resin is a quaternary amine anion exchange resin, or mixtures of these and other exchange resins.

The first and second ion exchange resins may contact the as-synthesized aqueous dispersion either simultaneously, or consecutively. For example, in one embodiment both resins are added simultaneously to an as-synthesized aqueous dispersion of an electrically conducting polymer, and allowed to remain in contact with the dispersion for at least about 1 hour, e.g., about 2 hours to about 20 hours. The ion exchange resins can then be removed from the dispersion by filtration. The size of the filter is chosen so that the relatively large ion exchange resin particles will be removed while the smaller dispersion particles will pass through. Without wishing to be bound by theory, it is believed that the ion exchange resins quench polymerization and effectively remove ionic and non-ionic impurities and most of unreacted monomer from the as-synthesized aqueous dispersion. Moreover, the basic, anion exchange and/or acidic, cation exchange resins renders the acidic sites more basic, resulting in increased pH of the dispersion. In general, about one to five grams of ion exchange resin is used per gram of new conductive polymer composition.

In many cases, the basic ion exchange resin can be used to adjust the pH to the desired level. In some cases, the pH can be further adjusted with an aqueous basic solution such as a solution of sodium hydroxide, ammonium hydroxide, tetra-methylammonium hydroxide, or the like.

In another embodiment, more conductive dispersions are formed by the addition of highly conductive additives to the aqueous dispersions of the new conductive polymer composition. Because dispersions with relatively high pH can be formed, the conductive additives, especially metal additives, are not attacked by the acid in the dispersion. Examples of suitable conductive additives include, but are not limited to metal particles and nanoparticles, nanowires, carbon nanotubes, graphite fibers or particles, carbon particles, and combinations thereof.

### 3. Electronic Devices

In another embodiment, there are provided electronic devices comprising the bilayer composition. The term “electronic device” is intended to mean a device including one or more organic semiconductor layers or materials. An electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

In one embodiment, the electronic device comprises at least one electroactive layer positioned between two electrical contact layers, wherein the device further includes a layer comprising a polymer made from the derivatized conductive monomer. The term “electroactive” when referring to a layer or material is intended to mean a layer or material that exhibits electronic or electro-radiative properties. An electroactive layer material may emit radiation or exhibit a change in concentration of electron-hole pairs when receiving radiation.

One type of device is an organic light-emitting diode (“OLED”). One such device is shown in FIG. 2. The device, 100, has an anode layer 110, a buffer layer 120, an optional hole transport layer 130, an electroactive layer 140, and a cathode layer 160. Adjacent to the cathode layer 150 is an optional electron-injection/transport layer 150. The buffer layer comprises a polymer made from at least one derivatized conductive monomer as described herein.

The device may include a support or substrate (not shown) that can be adjacent to the anode layer 110 or the cathode layer 160. Most frequently, the support is adjacent the anode layer 110. The support can be flexible or rigid, organic or inorganic. Examples of support materials include, but are not limited to, glass, ceramic, metal, and plastic films.

The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), indium-zinc-oxide, aluminum-tin-oxide, gold, silver, copper, and nickel. The anode may also comprise an organic material, especially a conducting polymer such as polyaniline, including exemplary materials as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

In one embodiment, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used.

The buffer layer 120 comprises a conductive polymer made from the derivatized conductive monomer described herein. In one embodiment, the buffer layer is formed by liquid deposition from a liquid composition. Any known liquid deposition technique can be used, including continuous and discontinuous techniques. Continuous liquid deposition techniques, include but are not limited to, spin coating, gravure coating, curtain coating, dip coating, slot-die coating, spray coating, and continuous nozzle coating. Discontinuous liquid deposition techniques include, but are not limited to, ink jet printing, gravure printing, flexographic printing and screen printing.

In one embodiment, the buffer layer is formed by liquid deposition from a liquid composition having a pH greater than 2. In one embodiment, the pH is greater than 4. In one embodiment, the pH is greater than 6. Any hole transport material may be used for the hole transport layer. In one embodiment the hole transport material has an optical band gap equal to or less than 4.2 eV and a HOMO level equal to or less than 6.2 eV with respect to vacuum level.

Any hole transport material may be used for the hole transport layer 130. In one embodiment the hole transport material has an optical band gap equal to or less than 4.2 eV and a HOMO level equal to or less than 6.2 eV with respect to vacuum level.

In one embodiment, the hole transport material comprises at least one polymer. Examples of hole transport polymers include those having hole transport groups. Such hole transport groups include, but are not limited to, carbazole, triarylamines, triarylmethane, fluorene, and combinations thereof. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In some embodiments, the hole transport layer comprises a hole transport polymer. In some embodiments, the hole transport polymer is a distyrylaryl compound. In some embodiments, the aryl group is has two or more fused aromatic rings. In some embodiments, the aryl group is an acene. The term “acene” as used herein refers to a hydrocarbon parent component that contains two or more ortho-fused benzene rings in a straight linear arrangement.

In some embodiments, the hole transport polymer is an arylamine polymer. In some embodiments, it is a copolymer of fluorene and arylamine monomers.

In some embodiments, the polymer has crosslinkable groups. In some embodiments, crosslinking can be accomplished by a heat treatment and/or exposure to UV or visible radiation. Examples of crosslinkable groups include, but are not limited to vinyl, acrylate, perfluorovinylether, 1-benzo-3,4-cyclobutane, siloxane, and methyl esters. Crosslinkable polymers can have advantages in the fabrication of solution-process OLEDs. The application of a soluble polymeric material to form a layer which can be converted into an insoluble film subsequent to deposition, can allow for the fabrication of multilayer solution-processed OLED devices free of layer dissolution problems.

Examples of crosslinkable polymers can be found in, for example, published US patent application 2005-0184287 and published PCT application WO 2005/052027.

In some embodiments, the hole transport layer comprises a polymer which is a copolymer of 9,9-dialkylfluorene and triphenylamine. In some embodiments, the polymer is a copolymer of 9,9-dialkylfluorene and 4,4′-bis(diphenylamino)biphenyl. In some embodiments, the polymer is a copolymer of 9,9-dialkylfluorene and TPB. In some embodiments, the polymer is a copolymer of 9,9-dialkylfluorene and NPB. In some embodiments, the copolymer is made from a third comonomer selected from (vinylphenyl)diphenylamine and 9,9-distyrylfluorene or 9,9-di(vinylbenzyl)fluorene.

In one embodiment, the hole transport layer comprises a non-polymeric hole transport material. Examples of hole transporting molecules include, but are not limited to: 4,4′,4″-tris(N,N-diphenyl-amino)triphenylamine (TDATA); 4,4′,4″-tris(N-3-methylphenyl-N-phenyl-amino)triphenylamine (MTDATA); N,N′-diphenyl-N,N′-bis(3-methylphenyl)-[1,1′-biphenyl]-4,4′-diamine (TPD); 1,1-bis[(di-4-tolylamino)phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine.

In one embodiment, the hole transport layer comprises a material having the Formula XVI:

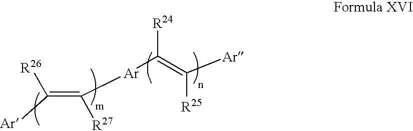

wherein
Ar is an arylene group;
Ar′, and Ar″ are selected independently from aryl groups;
R²⁴ through R²⁷ are selected independently from the group consisting of hydrogen, alkyl, aryl, halogen, hydroxyl, aryloxy, alkoxy, alkenyl, alkyny, amino, alkylthio, phosphino, silyl, —COR, —COOR, —PO₃R₂, —OPO₃R₂, and CN;
R is selected from the group consisting of hydrogen, alkyl, aryl, alkenyl, alkynyl, and amino; and
m and n are integers each independently having a value of from 0 to 5, where m+n≠0.
   In one embodiment of Formula XVI, Ar is an arylene group containing two or more ortho-fused benzene rings in a straight linear arrangement.

Depending upon the application of the device, the electroactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive material is an organic electroluminescent (“EL”) material. Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Optional layer 150 can function both to facilitate electron injection/transport, and can also serve as a confinement layer to prevent quenching reactions at layer interfaces. More specifically, layer 150 may promote electron mobility and reduce the likelihood of a quenching reaction if layers 140 and 160 would otherwise be in direct contact. Examples of materials for optional layer 150 include, but are not limited to, metal chelated oxinoid compounds, such as bis(2-methyl-8-quinolinolato)(para-phenyl-phenolato)aluminum(III) (BAlQ) and tris(8-hydroxyquinolato)aluminum (Alq₃); azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and any one or more combinations thereof. Alternatively, optional layer 140 may be inorganic and comprise BaO, LiF, Li₂O, or the like.

The cathode layer 160 is an electrode that is particularly efficient for injecting electrons or negative charge carriers. The cathode layer 150 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process. In some embodiments, the cathode layer will be patterned, as discussed above in reference to the anode layer 110.

Other layers in the device can be made of any materials which are known to be useful in such layers upon consideration of the function to be served by such layers.

In some embodiments, an encapsulation layer (not shown) is deposited over the contact layer 160 to prevent entry of undesirable components, such as water and oxygen, into the device 100. Such components can have a deleterious effect on the organic layer 140. In one embodiment, the encapsulation layer is a barrier layer or film. In one embodiment, the encapsulation layer is a glass lid.

Though not depicted, it is understood that the device 100 may comprise additional layers. Other layers that are known in the art or otherwise may be used. In addition, any of the above-described layers may comprise two or more sub-layers or may form a laminar structure. Alternatively, some or all of layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

In one embodiment, the different layers have the following range of thicknesses: anode 110, 500-5000 Å, in one embodiment 1000-2000 Å; the buffer 120, 50-2000 Å, in one embodiment 200-1000 Å, and the hole transport layer 130, 50-2000 Å, in one embodiment 200-1000 Å; electroactive layer 140, 10-2000 Å, in one embodiment 100-1000 Å; optional electron transport layer 150, 50-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. Thus the thickness of the electron-transport layer should be chosen so that the electron-hole recombination zone is in the light-emitting layer. The desired ratio of layer thicknesses will depend on the exact nature of the materials used.

In operation, a voltage from an appropriate power supply (not depicted) is applied to the device 100. Current therefore passes across the layers of the device 100. Electrons enter the organic polymer layer, releasing photons. In some OLEDs, called active matrix OLED displays, individual deposits of photoactive organic films may be independently excited by the passage of current, leading to individual pixels of light emission. In some OLEDs, called passive matrix OLED displays, deposits of photoactive organic films may be excited by rows and columns of electrical contact layers.

### EXAMPLES

The concepts described herein will be further described in the following examples, which do not limit the scope of the invention described in the claims.

### General Procedure for Film Sample Preparation and Kelvin Probe Measurement

The materials illustrated in Examples and Comparative Examples were spin-coated on 30 mm×30 mm glass/indium/tin semiconductive oxide (ITO) substrates. The ITO/glass substrates consist of 15 mm×20 mm ITO area at the center having ITO thickness of 100 to 150 nm. At one corner of 15 mm×20 mm ITO area, ITO film surface extended to the edge of the glass/ITO serves as electrical contact with one Kelvin probe electrode. Prior to spin coating, ITO/glass substrates were cleaned and the ITO side was subsequently treated with oxygen plasma for 15 minutes. Once spin-coated with an aqueous sample solution or dispersion, the deposited layer on the corner of the extended ITO film was removed with a water-wetted cotton-swath tip. The exposed ITO pad was used to make contact with a Kelvin probe electrode. The deposited film was then dried as described in Examples or Comparative Examples. The dried film samples were then placed in a glass container filled with nitrogen was kept capped until measurement.

For energy potential measurement, ambient-aged gold film was measured first as a reference prior to measurement of samples. The gold film on a same size of glass was placed in a cavity cut out at the bottom of a square steel container. On the side of the cavity, there are four retention clips to keep sample piece firmly in place. One of the retention clips is attached with electrical wire for making contact with a second electrode of the Kelvin probe. The gold film was facing up while a Kelvin probe tip protruded from the center of a steel lid was lowered to above the center of the gold film surface. The lid was then screwed tightly onto the square steel container at four corners. A side port on the square steel container was connected with a tubing to allow nitrogen to sweep the Kelvin probe cell while a nitrogen exit port was capped with a septum in which a steel needle was inserted to maintain ambient pressure. The probe settings were then optimized for the probe and only height of the tip was adjusted during the measurement. The Kelvin probe tip was connected to a McAllister KP6500 Kelvin Probe meter having the following parameters: 1) frequency: 230; 2) amplitude: 20; 3) DC offset: varied from sample to sample; 4) upper backing potential: 2 volt; 5) lower backing potential: −2 volt; 6) scan rate: 1; 7) trigger delay: 0; 8) acquisition(A)/data(D) points: 1024; 9) A/D rate: 12405@19.0 cycles; 10) D/A: delay: 200; 11) set point gradient: 0.2; 12) step size: 0.001; 13) maximum gradient deviation: 0.001. As soon as the tracking gradient stabilized, the contact potential difference or CPD (expressed in volts) between gold film and probe tip was recorded. The CPD of gold was then referenced to (4.7-CPD) eV (electron-volt). According to literature, the work function of an ambient-aged gold film surface is 4.7 eV [Surface Science, 316, (1994), P380]. CPD of gold was measured periodically while CPD of samples were being determined. Each sample was loaded into the cavity in the same manner as gold film sample. On the retention clip that makes electrical contact with the sample, extra care was taken to ensure that good electrical contact was made with the exposed ITO pad. During the CPD measurement a small stream of nitrogen was flown through the cell without disturbing the probe tip. Once CPD of a sample was recorded, energy potential or work function was calculated by adding CPD of the sample to the difference of 4.7 eV and CPD of gold. Energy potential calculated from CPD is a general term for any electrically conductive or non-conductive materials, but work function is only for electrically conductive or semiconductive materials. In the examples and comparative examples below, energy potential is used for the conjugated monomers, but work function is used for electrically conducting polymers made from the conjugated monomers.

### Example 1

This example illustrates the preparation of 2,3-dihydrothieno[3,4-b][1,4]dioxin-3-yl)methanol (EDOT-CH₂OH) for Example 2 and Comparative Example A.

### a) Synthesis of 3,4-dimethoxythiophene

This material can be purchased commercially or prepared as follows.

Sodium methoxide was prepared by slow addition of small cubes of sodium metal (25 g, 1.05 mol) to ice bath cooled anhydrous methanol (600 mL) in a 1 L three-necked flask equipped with a reflux condenser under a nitrogen blanket. Between additions, sodium was covered in kerosene to protect it from moisture. After complete dissolution of the metal, 50 g (0.207 mol) of 3,4-dibromothiophene, 16.5 g (0.207 mol) of copper (I) oxide, and 1.37 g (0.00827 mol) of potassium iodide were added to the reaction mixture. The mixture was refluxed for three days. The reaction was then cooled to room temperature and filtered through a sintered glass fritted funnel. The resulting solid was rinsed with ether and filtrate was poured into 500 mL water. The solution was then extracted with more ether. The organic fractions were combined and dried with magnesium sulfate. Solvent removal gave a light yellow oil. Vacuum distillation gave 26.2 g of a clear, colorless oil whose structure and purity were confirmed by ¹H and ¹³C NMR and GC-MS. Yield was 88% of theoretical.

### b) Synthesis of 2-(bromomethyl)-2,3-dihydrothieno[3,4-b][1,4]dioxine

Under nitrogen, 20.0 g (0.139 mol) of dimethoxythiophene, 25.0 g (0.161 mol) of 3-bromo-1,2-propanediol, and 5 g of p-toluenesulfonic acid were combined with 350 mL of toluene in a 500 mL round-bottom flask equipped with a reflux condenser and stir bar. The reaction mixture was sparged with nitrogen for 30 minutes, then heated to 100° C. overnight. Upon cooling to room temperature the reaction mixture was concentrated to ˜100 mL and poured into saturated potassium carbonate solution. The resulting solution was extracted with DCM. The combined extracts were washed with brine, then dried with magnesium sulfate. Solvent removal gave a black oil. The crude material was purified by column chromatography using 3:1 hexanes/DCM. Solvent removal gave a white solid that was dried under high vacuum overnight to give 18.6 g of material. The structure and purity were confirmed by ¹H/¹³C NMR and GC-MS. Yield was 57% of theoretical.

### c) Synthesis of (2,3-dihydrothieno[3,4-b][1,4]dioxin-2-yl)methyl acetate (EDOT-Meoac)

In a 50 mL Schlenk tube 1.00 g of 2-(bromomethyl)-2,3-dihydrothieno[3,4-b][1,4]dioxine was combined with 0.5 g (0.0051 mol) of potassium acetate and 25 mL of DMSO. The tube was sealed and stirred for 1 h at 100° C. At this time TLC indicated complete consumption of the starting material. The reaction was poured into water and extracted with ether. After removing the ether under reduced pressure column chromatography was performed using 90% methylene chloride in hexane to isolate a light yellow oil in 90% yield. The structure and purity were confirmed by ¹H/¹³C NMR and GC-MS.

### d) Synthesis of (2,3-dihydrothieno[3,4-b][1,4]dioxin-3-yl)methanol (EDOT-MeOH)

In a 25 mL round bottom flask equipped with a reflux condenser, 0.64 g (0.0030 mol) of (2,3-dihydrothieno[3,4-b][1,4]dioxin-2-yl)methyl acetate was combined with 50% NaOH in water. The reaction was refluxed overnight and then cooled to room temperature. It was then poured into an Erlenmeyer flask filled with 100 mL water. The mixture was acidified, then extracted with DCM. The solvent was removed under reduced pressure and column chromatography (7:3 hexanes/ethyl acetate) was performed to give 0.46 g (90%) of product. The structure was confirmed by LC-MS and ¹H/¹³C NMR.

### e) Synthesis of (2,3-dihydrothieno[3,4-b][1,4]dioxin-3-yl)methyl benzoate

In a 100 mL round bottom flask, 9.00 g (0.0382 mol) of 2-(bromomethyl)-2,3-dihydrothieno[3,4-b][1,4]dioxine, 6.39 g (0.0459 mol) of ammonium benzoate, and 55 g of DMSO were combined. The flask was equipped with a reflux condenser and the reaction mixture was heated at 100° C. overnight. After cooling to room temperature, the reaction mixture was poured into water and the product was extracted with methylene chloride. The organic fractions were combined and the solvent removed under reduced pressure. Purification by column chromatography provided 7.5 g (71% yield) of a white solid whose structure was confirmed by ¹H/¹³C NMR and LC-MS.

### f) Synthesis of (2,3-dihydrothieno[3,4-b][1,4]dioxin-3-yl)methanol (EDOT-CH2OH)

In a 100 mL round bottom flask, 7.5 g (0.027 mol) of (2,3-dihydrothieno[3,4-b][1,4]dioxin-3-yl)methyl benzoate was dissolved in a minimal amount of warm ethanol and dropwise added to a refluxing solution of 4.58 g (0.081 mol) of potassium hydroxide in 50 mL water. After heating overnight, the reaction was cooled to room temperature and acidified to pH 7 by dropwise addition of concentrated hydrochloric acid. The reaction mixture was extracted with methylene chloride. The organic fractions were combined and the solvent removed under reduced pressure. Purification by column chromatography provided 3.95 g (85% yield) of (2,3-dihydrothieno[3,4-b][1,4]dioxin-3-yl)methanol. Structure was confirmed by ¹H/¹³C NMR and LC-MS.

### Example 2

This example illustrates the preparation of a derivatized conductive monomer as described herein: 1,1,2,2-tetrafluoro-2-[1,2,2-trifluoro-2-(2,3-dihydrothieno[3,4-b]-1,4-dioxin-2-methyloxy)]-ethanesulfonic acid. The fluorinated acid substituent is a partially fluorinated sullfonic-acid. The energy potential is also determined.

1,1,2,2-Tetrafluoro-2-[(trifluoroethenyl)oxy]-ethanesulfonylfluoride (6 g, 21.4 mmol) was added to the slurry of lithium carbonate (1.59 g, 21.4 mmol) in methanol (20 ml) and stirred overnight at ambient temperature. Progress of the reaction was monitored by following the disappearance of the —SO₂F peak (40 ppm) in ¹⁹F NMR. Reaction mixture was filtered, acetonitrile (40 ml) and ethylene carbonate (5.4 g) were added to the solution and solvents were removed under reduced pressure. Leftover methanol was removed by azeotropic distillation with toluene as judged by

¹H NMR. Yield 5.2 g of white solid (PSVE-Li-EC). ¹H NMR (CDCl₃, ppm): 4.49 (s). ¹⁹F NMR (CDCl₃, ppm): −86.0 (app t, 2F, J=6.0 Hz), −117.7 (app dd, 1F, J=64.1, 88.3 Hz), −119.5 (app s, 2F), −124.9 (ddt, 1F, J=6.0, 88.1, 110.8 Hz), −136.6 (ddt, 1F, J=6.1, 64, 111 Hz).

In a drybox, lithium salt of 1,1,2,2-tetrafluoro-2-[(trifluoroethenyl)oxy]-ethanesulfonic acid (PSVE-Li-EC, 1.30 g, 3.5 mmol) and 2,3-dihydrothieno[3,4-b]-1,4-dioxin-2-methanol (EDOTCH₂OH, 0.6 g, 3.5 mmol) were dissolved in dry DMF (5 ml). Lithium tert-butoxide (42 mg, 0.5 mmol) was added and reaction mixture was stirred under ambient temperature. Reaction progress was monitored by ¹⁹F NMR by following the disappearance of the CF₂═CF— signals. Upon completion, DMF was removed under vacuum at 80° C. to afford of thick yellow oil, which was quickly rinsed with 3 ml of 1M aq. HCl. The residue was dried under vacuum at 80° C. to give 1.5 g of the product (79% yield). ¹H NMR (CDCl₃, ppm): 4.04-4.26 (m, 4H), 4.39 (m, 1H), 4.45 (s, 1.4H), 5.85 (d, 1H, J=54 Hz), 6.35 (app d, 1H) 6.38 (app d, 1H). ¹⁹F NMR (CDCl₃, ppm): −145.0 (ddt, 1F, J=6.1, 27.3, 54.1 Hz), −118.3 (m, 2F), −90.3 (m, 2F), −86.4 (app dd, 1F, J=78, 146 Hz), −82.9 (app dd, 1F, J=48, 146 Hz). The NMR confirms the structure of 1,1,2,2-tetrafluoro-2-[1,2,2-trifluoro-2-(2,3-dihydrothieno[3,4-b]-1,4-dioxin-2-methyloxy)]-ethanesulfonate. The structure is also shown as EDOT(ethylenedioxythiophene)-CH₂—OCF₂CHFOCF₂CF₂SO₃Li.

A small amount of the lithium salt of EDOT-CH₂—OCF₂CHFOCF₂CF₂SO₃H made above was dissolved in a small amount of water. The lithium salt solution was added with Dowex M31, a proton exchange resin, to convert the lithium salt to sulfonic acid. A few drops of the solution were spin-coated on an oxygen-plasma treated ITO/glass surface at 1,000 RPM for 60 seconds. The thin film was dried in a partial vacuum chamber flowed through with nitrogen. The dried film on ITO/glass was then loaded to the Kelvin probe cell. Contact potential difference (CPD) between the sample and probe tip was measured to be 0.85 V. Energy potential of EDOT-CH₂—O—CF₂CHFOCF₂CF₂SO₃H on the ITO/Glass was then calculated to be 4.95 eV based on a pre-determined CPD of air-aged gold film, which is 0.6 V. The EDOT attached with the highly fluorinated sulfonic acid has a higher energy potential than that of the non-fluorinated sulfonic acid attachment shown in Comparative Example 1. High energy potential of a conjugated monomer is required if one is to achieve high work-function conducting polymer which will be illustrated in Example 3.

### Example 3

This example illustrates polymerization of 1,1,2,2-tetrafluoro-2-[1,2,2-trifluoro-2-(2,3-dihydrothieno[3,4-b]-1,4-dioxin-2-methyloxy)]-ethanesulfonate acid (a conjugated monomer attached with a partially fluorinated sullfonic-acid), and work-function of the obtained conducting polymer.

0.3688 g (0.808 mmol) of the lithium salt prepared in Example 2 were first dissolved in 32.68 g of deionized water in a 125 mL Erlenmeyer flask. The solution was stirred with a stirrer while a stock solution of ferric sulfate was being made. 0.074 g ferric sulfate hydrate (97%, Sigma-Aldrich Corp., St. Louis, Mo., USA) was dissolved in deionized water to a total weight of 11.3662 g. 0.65 g (0.0082 mmol) of ferric sulfate solution was then added to the reaction mixture, followed with addition of 0.162 mL (2.02 mmol of HCl) of 37.87% (w/w) aqueous HCl solution. The mixture was stirred for 10 minutes before addition of a sodium persulfate solution. A stock solution was made first by adding water to 1.49 g of sodium persulfate (Fluka, Sigma-Aldrich Corp., St. Louis, Mo., USA) to total weight of 20.44 g. 3.173 mL of the solution containing 0.24 g (1.01 mmol) of sodium persulfate were pumped into the polymerization solution in 30 minutes. Polymerization was allowed to proceed with stirring at about 23° C. for 20.5 hours. Reaction mixture turned blue first and became much darker before the end of the experiment. A portion of the polymerization liquid was kept, while 21.27 g were transferred to a 30 mL plastic bottle with 0.65 g of DR-2030 (proton exchange resin from Dow Chemicals Company) and 1.97 g of Lewatit® MP62 WS (Bayer, Pittsburgh, Pa., USA). The mixture was allowed to stir for five hours. Before use, the two resins were separately washed with deionized water until no color was observed in the wash. After first resin treatment, the solids were filtered out and filtrate was treated with 0.65 g of DR-2030 and 1.97 g of Lewatit® MP62® WS again for five hours to ensure removal of chloride anion and lithium cation. 14.8 g of polymerization liquid was collected after removal of the resins. pH of the liquid was measured to be 2.1.

UV/Vis/Near-Infrared spectrum of a thin film cast on a quartz plate with the polymerization liquid shows that EDOT-CH₂—OCF₂CHFOCF₂CF₂SO₃H has polymerized to a conducting polymer. Absorption of the polymer film starts to rise at 500 nm and shows strong absorption at 2,500 nm. It is evident that EDOT polymer chain is partially oxidized having positive charges on the backbones. The positive charges are balanced by the sulfonate anions on monomers. Since sulfonate anions are part of the conjugated monomers, this class of conducting polymers is called self-doped conducting polymers.

A few drops of poly(EDOT-CH₂—OCF₂CHFOCF₂CF₂SO₃H) made as described above was spin-coated onto an oxygen-plasma treated ITO/glass surface at 1,040 RPM for 60 seconds. The thin film was dried on a hot plate in air at 120° C. for 7 minutes. The dried film on ITO/glass was then loaded to the Kelvin probe cell. Contact potential difference (CPD) between the sample and probe tip was measured to be 1.36 V. Work function of poly(EDOT-CH₂—O—CF₂CHFOCF₂CF₂SO₃H) on the ITO/Glass was then calculated to be 5.46 eV based on a pre-determined CPD of air-aged gold film, which is 0.6 V. The work-function is high, which is attributed to fluorinated sulfonic acid attachment to EDOT. EDOT modified with the fluorinated acid has energy potential of 4.96 eV as illustrated in Example 2. High energy potential of a conjugated monomer is required if one is to achieve high work function conducting polymer. It is noted here that 70% of the available hydrogen bonded to the carbons in the acid attachment has been replaced with fluorine.

### Example 4

This example illustrates polymerization of EDOT(ethylenedioxythiophene)-CH₂—OCF₂CHFOCF₂CF₂SO₃Li [1,1,2,2-tetrafluoro-2-[1,2,2-trifluoro-2-(2,3-dihydrothieno[3,4-b]-1,4-dioxin-2-methyloxy)]-ethanesulfonate], and electrical conductivity of obtained conducting polymers. The polymerization was carried out at 4° C.

Second polymerization batch was obtained according to the procedure described in Example 3, except that polymerization temperature was kept at 4° C. Resin treatment was also carried out in the same manner. pH of the conducting polymer dispersion, which is dark blue in color, was measured to be 2.2. Absorption of the polymer film starts to rise at 500 nm and shows strong absorption at 2,500 nm. Electrical conductivity of a dried film cast from the dispersion was measured to be

1×10⁻⁵ S/cm at room temperature.

### Comparative Example A

This comparative example illustrates the preparation of mixture of 4-(2,3-dihydrothieno[3,4-b][1,4]dioxin-2-yl)methoxy)butane-1-sulfonic acid and 4-(3,4-dihydro-2H-thieno[3,4-b][1,4]dioxepin-3-yloxy)butane-1-sulfonic acid (conjugated monomers containing non-fluorinated sulfonic acid substituents) and its energy potential.

A 7:3 mixture of (2,3-dihydrothieno[3,4-b][1,4]dioxin-2-yl)methanol and 3,4-dihydro-2H-thieno[3,4-b][1,4]dioxepin-3-ol was first prepared according to the procedure described in the paper of A. Lima, P. Schottland, A. Sadki, C. Chevrot, Synthetic Metals, 93, 33-41 (1998). The mixture was used for conversion to sodium sulfonate monomers with butanesultone. In a nitrogen filled dry box, 4.4 g (0.026 mol) of the 7:3 mixture of (2,3-dihydrothieno[3,4-b][1,4]dioxin-2-yl)methanol and 3,4-dihydro-2H-thieno[3,4-b][1,4]dioxepin-3-ol was dissolved in 10 mL anhydrous THF and dropwise transferred to a 100 mL flask containing 40 mL of anhydrous THF and 1.6 g (0.039 mol) of 60% dispersion of sodium hydride in mineral oil. The reaction was stirred for one hour. 5.3 g of butanesultone was added and the reaction mixture refluxed for three hours. The reaction was then cooled to room temperature and removed from the dry box. The solvent was removed under reduced pressure. Methanol was added dropwise to the solid to destroy the residual sodium hydride and the mixture was filtered. The collected solid was washed with methanol. The methanol was removed under reduced pressure. Hexane was added and the mixture was allowed to sit overnight under nitrogen. The resulting solid was filtered and dried under vacuum overnight to give 8.0 g of product as a 7:3 mixture of sodium 4-(2,3-dihydrothieno[3,4-b][1,4]dioxin-2-yl)methoxy)butane-1-sulfonate and sodium 4-(3,4-dihydro-2H-thieno[3,4-b][1,4]dioxepin-3-yloxy)butane-1-sulfonate in 93% yield. The structure was confirmed by 1H/13C NMR and LC-MS. Sodium 4-(2,3-dihydrothieno[3,4-b][1,4]dioxin-2-yl)methoxy)butane-1-sulfonate is also known as EDOT(ethylenedioxythiophene)-CH₂—O—CH₂CH₂CH₂CH₂SO₃Na. 3,4-dihydro-2H-thieno[3,4-b][1,4]dioxepin-3-ol is also known as PropOT(propylenedioxythiophene)-O—CH₂CH₂CH₂CH₂SO₃Na.

0.634 g of the mixture of sodium salts made above was dissolved in 16.9283 g of deionized water. The sodium salts solution was treated with 2.24 g of Amberlyst 15, a proton exchange resin, to convert the sodium salt to sulfonic acid. The Amberlyst 15 resin was removed by filtration. The resulting clear solution was treated with additional 2.24 g of Amberlyst 15 to ensure complete conversion of the sodium sulfonate to sulfonic acid. Clear liquid was collected and a few drops of the solution were spin-coated on an oxygen-plasma treated ITO/glass surface at 1,000 RPM for 60 seconds. The thin film was dried in a partial vacuum chamber filled with nitrogen. The dried film on ITO/glass was then loaded into the Kelvin probe cell. Contact potential difference (CPD) between the sample and probe tip was measured to be 0.15 V. Energy potential of the non-fluorinated acid mixture on the ITO/Glass was then calculated to be 4.22 eV based on a pre-determined CPD of air-aged gold film (0.6 V). The mixture of monomers modified with non-fluorinated sulfonic acid has a lower energy potential than that with the partially fluorinated sulfonic acid (cf. Example 2).

### Comparative Example B

This example illustrates polymerization of mixture of 4-(2,3-dihydrothieno[3,4-b][1,4]dioxin-2-yl)methoxy)butane-1-sulfonate and 4-(3,4-dihydro-2H-thieno[3,4-b][1,4]dioxepin-3-yloxy)butane-1-sulfonate (conjugated monomers attached with non-fluorinated sulfonate) and the work function of obtained conducting polymers.

The mixture of EDOT(ethylenedioxythiophene)-CH₂—O—CH₂CH₂CH₂CH₂SO₃Na and PropOT(propylenedioxythiophene)-O—CH₂CH₂CH₂CH₂SO₃Na (1.5 g) was dissolved in 37.51 g of deionized water. 1.94 g of Amberlyst 15, a proton exchange resin, were added to the sodium salt solution to convert the sodium salt to sulfonic acid. After the conversion, the solid content was determined to be 4.12% in water. 24.27 g of the solution containing 1.0 g (3.243 mmol) of solids and 10.84 g of deionized water were placed in a 125 mL Erlenmeyer flask. The solution was stirred while a stock solution of ferric sulfate was being made. 0.0663 g of ferric sulfate hydrate (97%, Sigma-Aldrich Corp., St. Louis, Mo., USA) was dissolved in deionized water to a total weight of 10.203 g. 2.63 g of the ferric sulfate solution (0.0171 mmol of ferric sulfate) was then added to the reaction mixture. The mixture was stirred for 10 minutes before addition of a sodium persulfate solution. A stock solution of was first made by adding water to 0.97 g of sodium persulfate (Fluka, Sigma-Aldrich Corp., St. Louis, Mo., USA) to a total weight of 13.24 g. 12.73 mL of the solution containing 0.97 g (4.074 mmol) of sodium persulfate was pumped into the polymerization solution over 10 minutes. Polymerization was allowed to proceed with stirring at about 23° C. for 17.5 hours. The final solution was measured to have pH of 1.1 and was found to form dark green film.

A few drops of the mixture of poly(EDOT-CH₂—O—CH₂CH₂CH₂CH₂SO₃H) and Poly(PropOT-O—CH₂CH₂CH₂CH₂SO₃H) prepared as described above were spin-coated on an oxygen-plasma treated ITO/glass surface at 1,020 RPM for 60 seconds. The thin film was dried on a hot plate in air at 120° C. for 7 minutes. The dried film on ITO/glass was then loaded to the Kelvin probe cell. Contact potential difference (CPD) between the sample and probe tip was measured to be 0.3 V. Work-function of the conducting polymer mixture on the ITO/Glass was then calculated to be 4.4 eV based on a pre-determined CPD of air-aged gold film, which is 0.6 V. The work-function is low, which is much lower than 5.46 eV illustrated in Example 2 because the monomer mixture doesn't contain fluorinated sulfonic acids attached to EDOT and PropOT.

### Example 5

This example illustrates the synthesis of 2-[4-(3-thiophene-octafluorobutoxy)]-1,1,2,2-tetrafluoroethanesulfonate], a monomer having a perfluorosulfonate substituent attached to thiophene at position 3.

6.0 g (28.6 mmol) of 3-iodothiophene, 17.0 g (32.3 mmol) of 2-(4-iodo-octafluorobutoxy)-1,1,2,2-tetrafluoroethanesulfonyl fluoride, and 5.0 g of copper (78.7 mmol) were added to 30.ml of dimethylformamide (DMF) in a round-bottom flask. The mixture was stirred at 110° C. for 18 hours under nitrogen. The reaction mixture was then allowed to cool to room temperature. Ether (100 mL) was added to the reaction mixture and it was filtered to remove solids, which were then washed with ether. The ether layer was separated and washed with deionized water containing 1 mL of 5% aqueous HCl to remove haze. The ether layer was washed with brine and dried over MgSO₄. The slurry was filtered and volatiles was evaporated to yield 9.78 g of a residue, which was distilled at ˜47° C. and 0.35 mm Hg pressure to produce 6.83 g of clear liquid. This fraction is identified to be 2-[4-(3-thieophene-octafluorobutoxy)]-1,1,2,2-tetrafluoroethanesulfonyl fluoride.

2-[4-(3-Thiophene-octafluorobutoxy)]-1,1,2,2-tetrafluoroethanesulfonyl fluoride (5.71 g, 11.84 mmol) was added to a single-neck 250 mL round-bottom flask. Next, 51.1 g of methanol and 5.95 g of sodium carbonate were added. Once addition was complete, the flask was capped with an inlet adapter. The reaction mixtured was left to stir for 48 hours. Reaction mixture was filtered and volatiles were removed under vacuum to give a whitish solid, which was identified to be a sodium salt of 2-[4-(3-thieophene-octafluorobutoxy)]-1,1,2,2-tetrafluoroethanesulfonic acid.

### Example 6

This example illustrates energy potential of 2-[4-(3-thiophene-octafluorobutoxy)]-1,1,2,2-tetrafluoroethanesulfonate in acidic form.

Sodium salt of 2-[4-(3-thiophene-octafluorobutoxy)]-1,1,2,2-tetrafluoroethanesulfonic acid (0.6351 g, prepared as described in in Example 5) was mixed with 16.9407 g of deionized water. 2.24 g of Amberlyst 15, an acid exchange resin, were added to the solution. The reaction mixture was stirred to exchange sodium for proton. The resin was filtered off and the solution was found to have pH=1.56, indicating that 2-[4-(3-thiophene-octafluorobutoxy)]-1,1,2,2-tetrafluoroethanesulfonate is in the acidic form. A few drops of the solution were spin-coated on an oxygen-plasma treated ITO/glass surface at 1,800 RPM for 60 seconds. The thin film was dried in a partial vacuum chamber filled with nitrogen. The dried film was then loaded into the Kelvin probe cell. Contact potential difference (CPD) between the sample and probe tip was measured to be 1.52 V. Energy potential of thiophene-(CF₂)₄—O—(CF₂)₂—SO₃H on the ITO/Glass was calculated to be 5.52 eV based on a pre-determined CPD of air-aged gold film, which is 0.7 V. The EDOT monomer modified with the perfluorinated sulfonic acid has a much higher energy potential than that of non-fluorinated sulfonic acid attachment illustrated in Comparative Example 1. It is also higher than that of the partially fluorinated sulfonic acid attachment illustrated in Example 2. It is evident that perfluorosulfonic acid attached to conjugated monomers has highest energy potential.

### Example 7

This example illustrates the energy potential of 2-[4-(3-thiophene-octafluorobutoxy)]-1,1,2,2-tetrafluoroethanesulfonate in salt form.

The aqueous 2-[4-(3-thiophene-octafluorobutoxy)]-1,1,2,2-tetrafluoroethanesulfonic acid solution prepared as described in Example 6 was treated with a dilute sodium hydroxide solution to adjust its pH from 1.56 to pH 6.95. A few drops of the solution were spin-coated on an oxygen-plasma treated ITO/glass surface at 1,000 RPM for 60 seconds. The thin film was dried in a partial vacuum chamber filled with nitrogen. The dried film on ITO/glass was then loaded into the Kelvin probe cell. Contact potential difference (CPD) between the sample and probe tip was measured to be 0.81 V. Energy potential of thiophene-(CF₂)₄—O—(CF₂)₂—SO₃Na on the ITO/Glass was then calculated to be 4.9 eV based on a pre-determined CPD of air-aged gold film, which is 0.63 V. The EDOT monomer modified with the perfluorinated sodium sulfonate has a much lower energy potential than that of its counter part of sulfonic acid. However, it is still high in comparison with the non-fluorinated attachment in acidic form as illustrated in Comparative Example 1. This illustration shows that the conducting polymers made from self-doped monomers can be adjusted to high pH and still maintain high work function.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A derivatized conductive monomer having the formula:
PCM-(FAS),
wherein:
PCM is a precursor conductive monomer,
FAS is a fluorinated acid substituent, and
x is an integer from 1-5.

2. The monomer of claim 1, wherein PCM is selected from the group consisting of thiophenes, pyrroles, anilines, and polycyclic aromatics.

3. The monomer of claim 1, wherein FAS is highly fluorinated.

4. The monomer of claim 1, wherein FAS is fully fluorinated.

5. The monomer of claim 1, wherein FAS has acidic groups selected from the group consisting of sulfonic acid and sulfonamide.

6. The monomer of claim 1, wherein FAS is a substituent group selected from the group consisting of alkyl groups, alkoxy groups, amido groups, ether groups, and combinations thereof.

7. A polymer made from the derivatized conductive monomer of claim 1.

8. An organic electronic device having at least one layer comprising the polymer of claim 7.

9. An electronic device comprising at least one electroactive layer positioned between two electrical contact layers, wherein the device further includes a layer comprising a polymer made from the derivatized conductive monomer of claim 1.
